(19) United States
(12) Patent Application Publication
(10) Pub. No.: US 2024/0154068 A1
(43) Pub. Date: May 9, 2024

(54) LIGHT-EMITTING DEVICE

(71) Applicant: TIANJIN SANAN OPTOELECTRONICS CO., LTD., Tianjin (CN)

(72) Inventors: Yuehua JIA, Tianjin (CN); Weihuan LI, Tianjin (CN); Huan-Shao KUO, Tianjin (CN); Yu-Ren PENG, Tianjin (CN); Duxiang WANG, Tianjin (CN)

(21) Appl. No.: 18/492,582

(22) Filed: Oct. 23, 2023

(30) Foreign Application Priority Data
Nov. 3, 2022 (CN) 202211370494.3

(51) Int. Cl. H01L 33/38; H01L 33/14

(52) U.S. Cl. CPC H01L 33/385; H01L 33/145

(57) ABSTRACT

A light-emitting device includes: an epitaxial structure that has a first surface and a second surface; a first metal electrode that is disposed on the first surface, and that includes a main electrode and extending electrodes; current transmission blocks that are disposed on the second surface, and each having an electrode-facing sidewall and a non-electrode-facing sidewall; and a current blocking layer that is disposed in spaces among the current transmission blocks.

### CROSS-REFERENCE TO RELATED APPLICATION

This application claims priority to Chinese Invention Patent Application No. 202211370494.3, filed on Nov. 3, 2022, which is incorporated by reference herein in its entirety.

### FIELD

The disclosure relates to semiconductor manufacturing technology, and more particularly to a light-emitting device and a light-emitting apparatus.

### BACKGROUND

A light-emitting diode (LED) is a semiconductor light-emitting device typically made of a semiconductor material such as GaN, GaAs, GaP, GaAsP, etc. The light-emitting diode has a PN structure having a light-emitting property. Under a forward voltage, electrons flow from an N-region to a P-region, holes flow from the P-region to the N-region, and the electrons and the holes are recombined to emit light. The light-emitting diode has advantages of high luminous intensity, high efficiency, small size and long lifespan, and is widely applied in various fields.

A conventional light-emitting diode includes a horizontal type and a vertical type. In the vertical type of the light-emitting diode, electrodes are disposed at top and bottom of the light-emitting diode to allow a current to flow vertically therethrough. Compared to the horizontal type of the light-emitting diode, the vertical type of light-emitting diode may effectively improve technical problems such as light absorption caused by an epitaxial growth substrate, current crowding, and poor heat dissipation. When the current is injected to an electrode at the top of the light-emitting diode, the current is transmitted from the electrode at the top of the light-emitting diode through a plurality of current transmission blocks to the electrode at the bottom of the light-emitting diode, thereby ensuring uniform current distribution and avoiding current crowding.

However, since the current transmission blocks are dot shaped, when the current flows from the electrode at the top to the current transmission blocks, several problems arise. First, the current flows in a curved manner spatially, which largely limits transmission of the current, and the current transmitted per unit of time is also limited due to vertical cross sections of the current transmission blocks being limited. Second, the current may be accumulated at the vertical cross sections of the current transmission blocks, which are narrow, thereby causing the current not be able to be transmitted quickly and heat not be able to be dissipated quickly. Accordingly, the forward voltage becomes high, a hot-cold factor is low, and thermal saturation is poor. Therefore, optimizing current transmission is one of the technical challenges to be achieved by those skilled in the art.

### SUMMARY

Therefore, an object of the disclosure is to provide a light-emitting device that can alleviate at least one of the drawbacks of the prior art.

According to the disclosure, the light-emitting device includes an epitaxial structure, a first metal electrode, a plurality of current transmission blocks, and a current blocking layer.

The epitaxial structure has a first surface and a second surface opposite to the first surface.

The first metal electrode is disposed on the first surface of the epitaxial structure. The first metal electrode includes a main electrode and a plurality of extending electrodes that extend in an extending direction.

The plurality of current transmission blocks are disposed on the second surface of the epitaxial structure and that are disposed between two adjacent ones of the extending electrodes. For each of the two adjacent ones of the extending electrodes, each of those of the current transmission blocks that are adjacent to one side of the extending electrode has an electrode-facing sidewall that faces the one side of the extending electrode, and that is non-curved and parallel to an imaginary perpendicular surface which passes through the extending electrode and extends in the extending direction, and a non-electrode-facing sidewall that is distal to the one side of the extending electrode. The imaginary perpendicular surface is a normal surface that is perpendicular to the first surface.

The current blocking layer is disposed in spaces among the current transmission blocks.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an embodiment of a light-emitting device according to the disclosure.

FIG. 2 is a schematic view illustrating another embodiment of the light-emitting device according to the disclosure.

FIG. 3 is a schematic top view illustrating, in an embodiment of the light-emitting device according to the disclosure, relative positions of current transmission blocks and extending electrodes when the current transmission blocks are hexagonal prisms.

FIG. 4 is a schematic top view illustrating, in another embodiment of the light-emitting device according to the disclosure, relative positions of the current transmission blocks and the extending electrodes when the current transmission blocks are hexagonal prisms.

FIG. 5 is a schematic top view illustrating, in yet another embodiment of the light-emitting device according to the disclosure, relative positions of the current transmission blocks and the extending electrodes when the current transmission blocks are hexagonal prisms.

FIG. 6 is a schematic top view illustrating, in an embodiment of the light-emitting device according to the disclosure, relative positions of the current transmission blocks and the extending electrodes when the current transmission blocks are pentagonal prisms.

FIG. 7 is a schematic top view illustrating, in an embodiment of the light-emitting device according to the disclosure, relative positions of the current transmission blocks and the extending electrodes when the current transmission blocks are pentagonal prisms and rectangular prisms.

FIG. 8 is table illustrating results of a hot-cold factor test for a conventional light-emitting device having conventional current transmission blocks and the light-emitting device having the current transmission blocks of FIG. 7.

FIG. 9 is a graph illustrating a relationship between current and LPW for each of the conventional light-emitting device and the light-emitting device having the current transmission blocks of FIG. 7 under a cold temperature of 25° C. in the hot-cold factor test.

FIG. 10 is a graph illustrating the relationship between current and LPW for each of the conventional light-emitting device and the light-emitting device having the current transmission blocks of FIG. 7 under a hot temperature of 85° C. in the hot-cold factor test.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 1, an embodiment of a light-emitting device according to the present disclosure includes an epitaxial structure 10, a first metal electrode 20, a plurality of current transmission blocks 30, and a current blocking layer 42.

The epitaxial structure 10 is formed on a growth substrate using methods such as physical vapor deposition (PVD), chemical vapor deposition (CVD), epitaxy growth technology, and atomic layer deposition (ALD). The epitaxial structure 10 has a first surface (S1) and a second surface (S2) opposite to the first surface (S1), and includes a first semiconductor layer 11, an active layer 12, and a second semiconductor layer 13 sequentially disposed in such order in a laminating direction from the first surface (S1) to the second surface (S2). The epitaxial structure 10 may also include other layers such as a current spreading layer, a window layer, or an ohmic contact layer. Various different layers having different doping concentrations or component contents may be disposed.

The first semiconductor layer 11 and the second semiconductor layer 13 have different conductivity, electrical properties and polarity, and may provide electrons or holes based on doping elements. For example, when the first semiconductor layer 11 is n-type doped, the second semiconductor layer is p-type doped, and the active layer 12 is disposed between the first semiconductor layer 11 and the second semiconductor layer 13, the electrons and the holes are recombined in the active layer 12 driven by a current, and electrical energy is converted into light, thereby emitting light. By changing the physical properties and chemical composition of one or more layers in the active layer 12, a wavelength of the light emitted by the light-emitting device may be adjusted. In the present embodiment, the first semiconductor layer 11 is n-type doped, and the second semiconductor layer 13 is p-type doped.

The active layer 12 is a region where the electrons and the holes recombine for light emitting, and materials for the active layer 12 may vary depending on a desired wavelength of the light emitted by the active layer 12. The active layer 12 may have a single heterostructure (SH), a double heterostructure (DH), a double-sided double heterostructure (DDH), or a multi-quantum well (MQW) structure. The active layer 12 includes a well layer and a barrier layer, and the barrier layer has a band gap greater than that of the well layer. By adjusting a composition of semiconductor material of the active layer 12, the active layer 12 may emit a pre-determined wavelength of light. In this embodiment, the active layer 12 may emit red light, yellow light, or blue light. To improve light-emitting efficiency of the active layer 12, depth of the quantum wells, the number of pairs of the well layer and the barrier layer, thicknesses, and/or other features may vary.

Referring to FIG. 1, the first metal electrode 20 is disposed on the first surface (S1) of the epitaxial structure 10, and includes a main electrode 21 and a plurality of extending electrodes 22 that extend in an extending direction perpendicular to the laminating direction. The first metal electrode 20 is electrically connected to the first semiconductor layer 11, and may have a single-layer structure, a double-layer structure, or a multilayer structure. In some embodiments, the main electrode 21 may be designed to have a shape, such as cylinder, cube, or polygon according to actual requirements. Each of the extending electrodes 22 may have a pre-determined shape. In certain embodiments, the extending electrodes 22 are stripes that are parallel to each other, and an end portion of each of the extending electrodes 22 is electrically connected to the main electrode 21. The main electrode 21 and the extending electrodes 22 may be independently made of Ge, Au, Ni or combinations thereof, and may further include a metal material capable of forming good ohmic contact with the epitaxial structure 10.

The current transmission blocks 30 are disposed on the second surface (S2) of the epitaxial structure 10 and are disposed between two adjacent ones of the extending electrodes 22. In some embodiments, the current transmission blocks 30 may be made of a metallic material, e.g., AuZn, BeAu, GeNi or other alloy materials, or a transparent conductive material, e.g., ITO, InO, SnO, CTO, ATO, ZnO or combinations thereof. In this embodiment, the current transmission blocks 30 are made of the transparent conductive material. In one embodiment, to prevent the current being accumulated under the extending electrodes 22 thereby causing uneven light-emitting, a projection of each of the current transmission blocks 30 on the first surface (S1) of the epitaxial structure 10 falls outside a projection of each of the extending electrodes 22 on the first surface (S1) of the epitaxial structure 10.

Conventional current transmission blocks are small and dot shaped, so horizontal and vertical cross sections of the conventional current transmission blocks are small, thereby causing the current transmitted per unit of time being limited. In particular, in case of large currents, the current may be accumulated at the vertical cross sections of the current transmission blocks, which are narrow. When the current is unable to be transmitted and heat is unable to be dissipated, forward voltage becomes high, hot-cold factor is low, and thermal saturation is low. In addition, because the conventional current transmission blocks are designed to be farther away from the extending electrodes 22, the current transmitted to the current transmission blocks 30 flows in a curved manner spatially. That is to say, the current flows along a curved sidewall of each of the conventional dot shaped current transmission blocks, thereby limiting the transmission of current.

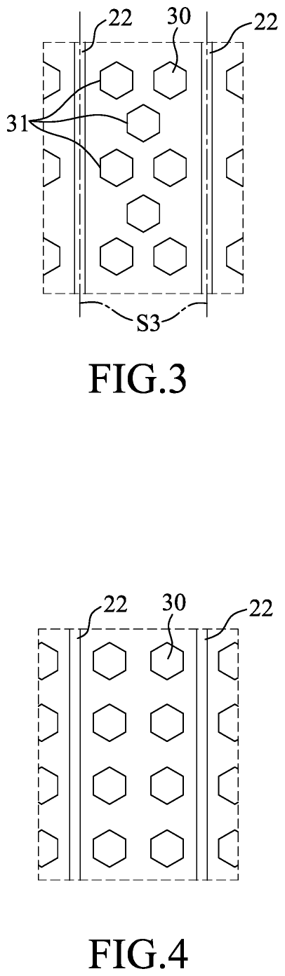

To resolve the abovementioned problem, for each of the two adjacent ones of the extending electrodes 22, each of those of the current transmission blocks 30 that are adjacent to one side of the extending electrode 22 has an electrode-facing sidewall 31 that faces the one side of the extending electrode 22, and that is non-curved and parallel to an imaginary perpendicular surface (S3) which passes through and extends in the extending direction, and a non-electrode-facing sidewall 32 that is distal to the one side of the extending electrode 22. The imaginary perpendicular surface (S3) is a normal surface that is perpendicular to the first surface (S1). When the electrode-facing sidewalls 31 are non-curved, areas of the current transmission blocks 30 for current transmission may be increased, thereby increasing the current transmitted per unit of time to prevent the current from being accumulated at the electrode-facing sidewalls 31 of the current transmission blocks 30. Meanwhile, the current and heat may be transmitted faster, the hot-cold factor may be increased, and the thermal saturation may be ensured. Furthermore, by having the electrode-facing sidewalls 31 parallel to the imaginary perpendicular surface (S3), the current may be transmitted in a parallel manner spatially from the extending electrodes 22 to the current transmission blocks 30 (referring to FIG. 3, in which the electrode-facing sidewalls 31 are parallel to the extending electrodes 22), thereby facilitating efficiency of the transmission of current.

It should be noted that the aforementioned non-electrode-facing sidewalls 32 of the current transmission blocks 30 may be curved, while the electrode-facing sidewalls 31 stay non-curved. For example, the current transmission blocks 30 may each be a semi-cylinder or a semi-arc cylinder. The non-electrode-facing sidewalls 32 may also be non-curved. For example, the current transmission blocks 30 may each be a polyhedron. In addition, the non-electrode-facing sidewalls 32 may be both curved and non-curved. For example, a horizontal cross section of each of the current transmission blocks 30 may have a runway shape or a half runway shape.

In certain embodiments, the electrode-facing sidewalls 31 of the current transmission blocks 30 are axisymmetric so as to optimize uniformity of current spreading. In other embodiments, each of the horizontal cross sections of the current transmission blocks 30 has an axisymmetric shape. For two adjacent ones of the extending electrodes 22, those of the current transmission blocks 30 that are between the two adjacent ones of the extending electrodes 22 are disposed in a symmetrical and uniform manner, thereby optimizing the uniformity of current spreading and improving performance of current spreading.

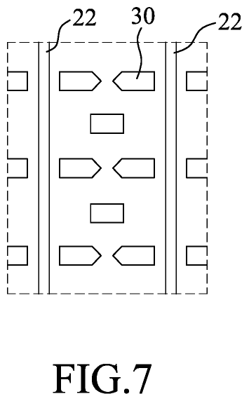

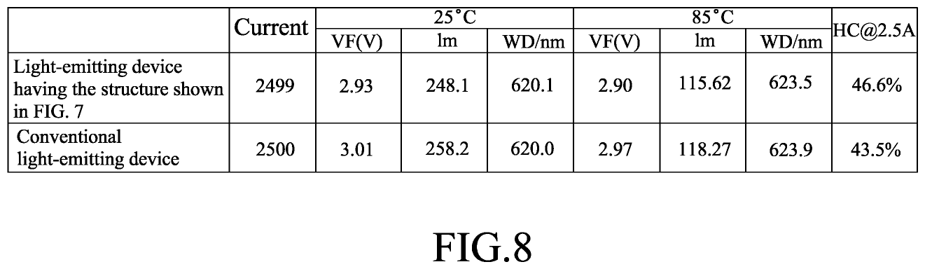

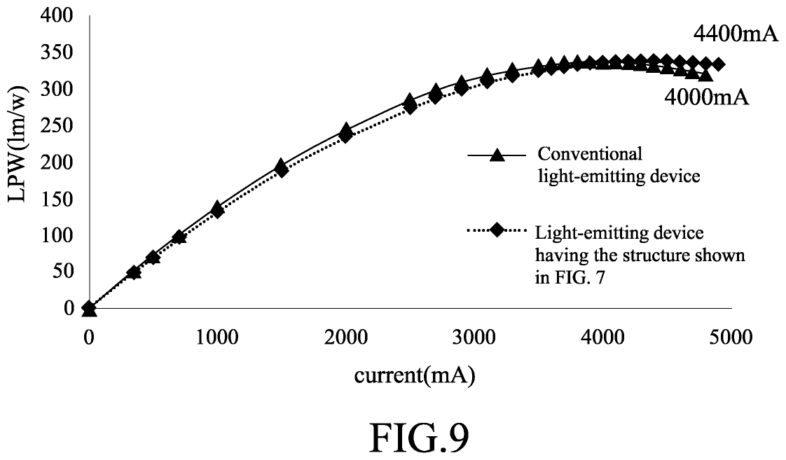

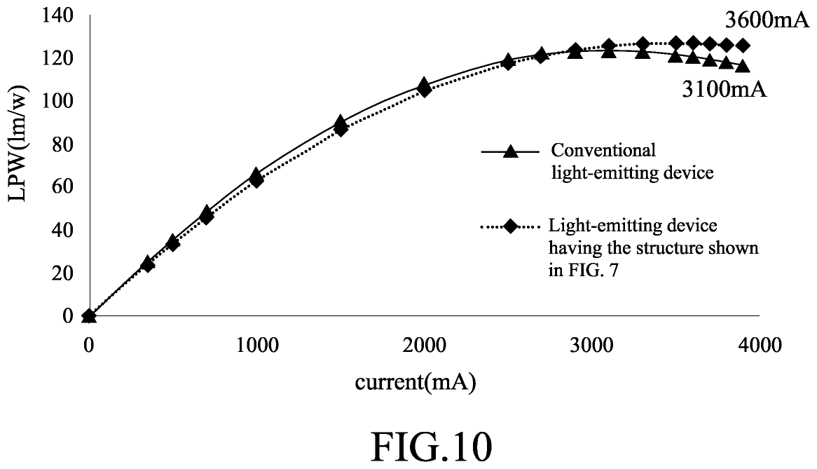

In some other embodiments, the current transmission blocks 30 are prisms. The current transmission blocks 30 may be hexagonal prisms, pentagonal prisms, quadrangular prisms, or combinations thereof. Referring to FIGS. 3, 4, 5, the current transmission blocks 30 are regular hexagonal prisms. Referring to FIG. 6, the current transmission blocks 30 are regular pentagonal prisms. Referring to FIG. 7, the current transmission blocks 30 are a combination of regular quadrangular prisms and pentagonal prisms. It should be further noted that, in a light-emitting device, the current transmission blocks 30 may have different combinations of various prisms. For example, the light-emitting device may include the current transmission blocks 30 that are hexagonal prisms and the current transmission blocks 30 that are pentagonal prisms.

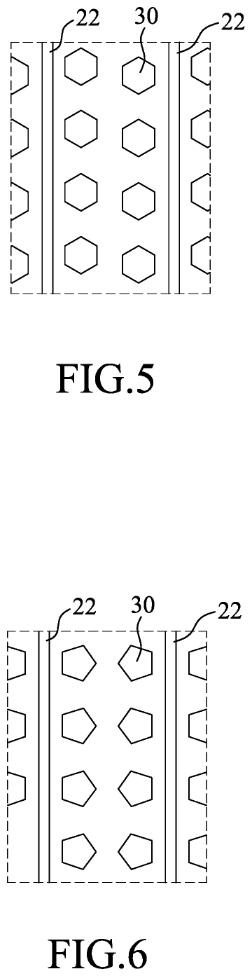

The current transmission blocks 30 are disposed in a symmetrical manner between two adjacent ones of the extending electrodes 22 that are parallel to each other, as shown in FIG. 4, or may be disposed in a misaligned manner as shown in FIG. 5. Particularly, in the case where the current transmission blocks 30 are disposed more densely (closer to each other), by disposing the current transmission blocks 30 in a uniform manner as shown in FIG. 3 or FIG. 5, the forward voltage will not increase while luminous intensity may be increased, thereby avoiding light-emitting interference caused by a dense arrangement of the current transmission blocks 30.

For example, the current transmission blocks 30 having the arrangement shown in FIG. 7 are applied to a light-emitting device. The light-emitting device is injected with a current of 2.5 A for a hot-cold factor test under a cold temperature of 25° C. and a hot temperature of 85° C., and is compared with a conventional light-emitting device with the conventional current transmission blocks. The conventional current transmission blocks have circular dot shapes and are same in number as the current transmission blocks 30 shown in FIG. 7. The results of the test are shown in the table of FIG. 8. As can be seen from the table, the hot-cold (HC) factor of the light-emitting device having the current transmission blocks 30 shown in FIG. 7 (i.e., 46.6%) is 3.1% higher compared to that of the conventional light-emitting device (i.e., 43.5%). Furthermore, FIG. 9 is a graph of the relationship between current and LPW for each of the light-emitting device having the current transmission blocks 30 of FIG. 7 and the conventional light-emitting device at 25° C. FIG. 10 is a graph of the relationship between current and LPW for each of the light-emitting device having the current transmission blocks 30 of FIG. 7 and the conventional light-emitting device at 85° C. As can be seen from FIG. 9 and FIG. 10, the thermal saturation point of the light-emitting device having the current transmission blocks 30 of FIG. 7 is 0.3 A higher compared with that of the conventional light-emitting device.

In an embodiment, for each of the two adjacent ones of the extending electrodes 22, a projection, on the imaginary perpendicular surface (S3), of the electrode-facing sidewall 31 of each of those of the current transmission blocks 30 that faces the one side of the extending electrode 22 has a length in the extending direction, and a ratio of a sum of the lengths of the projections of the electrode-facing sidewalls 31 of those of the current transmission blocks 30 to a length of the extending electrode 22 in the extending direction is no greater than 0.9. In another embodiment, the ratio ranges from 0.3 to 0.8. By virtue of positioning the current transmission blocks 30 in such way, large current spreading may be facilitated, thereby avoiding current being accumulated when the current is large.

Referring to FIG. 3 as an example, the ratio may be expressed as (5*a length of a side of a regular hexagon)/the length of the adjacent one of the extending electrodes 22. Referring to FIG. 4 as an example, the ratio may be expressed as (4*the length of the side of the regular hexagon)/the length of the adjacent one of the extending electrodes 22. Referring to FIG. 5 as an example, the ratio may be expressed as (4*the length of the side of the regular hexagon)/the length of the adjacent one of the extending electrodes 22. Referring to FIG. 6 as an example, the ratio may be expressed as (4*a length of a side of a regular pentagon)/the length of the adjacent one of the extending electrodes 22. Referring to FIG. 7 as an example, the current transmission blocks 30 satisfying the above requirement are the five current transmission blocks 30 that face one of the perpendicular surfaces (S3). That is to say, the ratio may be expressed as [(3*a length of an electrode-facing sidewall of a pentagon)+(2*a length of an electrode-facing sidewall of a rectangle)]/the length of the adjacent one of the extending electrodes 22.

The current blocking layer 42 is disposed in spaces among the current transmission blocks 30, i.e., the current blocking layer 42 forms a number of openings for disposal of the current transmission blocks 30. In some embodiments, the current blocking layer 42 contains an oxide material, a nitride material, a fluoride material or combinations thereof, in particular such as ZnO, SiO₂, SiOₓ, SiOₓN_{y}, Si₃N₄, Al₂O₃, TiOₓ, MgF, GaF or combinations thereof. In certain embodiments, the current blocking layer 42 includes one or multiple dielectric layers of different refractive indices. In yet some embodiments, the current blocking layer 42 is a light-transmissive dielectric layer through which at least 50% of light may pass. In other embodiments, a refractive index of the current blocking layer 42 is lower than a refractive index of the epitaxial structure 10.

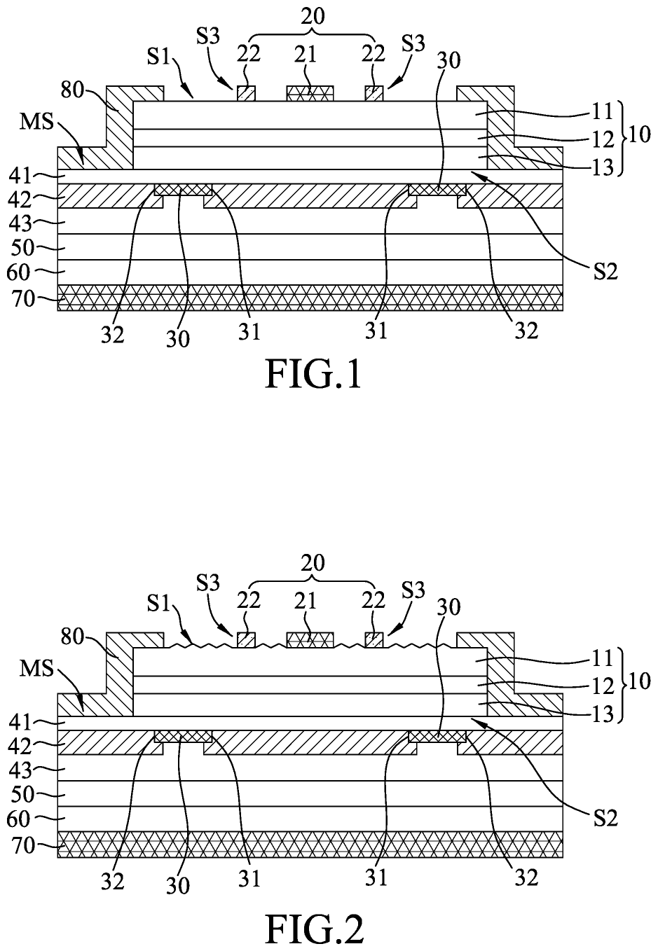

In an optional embodiment, referring to FIG. 2, the light-emitting device further includes a current spreading layer 41 that is disposed between the epitaxial structure 10 and the current blocking layer 42 for providing current spreading in the light-emitting device, thereby preventing current crowding and increasing the optoelectrical property of the light-emitting device. In addition, the current spreading layer 41 may also form ohmic contact with the current transmission blocks 30. As such, the current spreading layer 41 may be made of GaP, AlGaAs, GaN, etc. In this embodiment, the current spreading layer 41 is made of GaP for optimizing current spreading and forming the ohmic contact with the current transmission blocks 30.

The light-emitting device may further include an insulation layer 80 that covers a sidewall of the epitaxial structure 10 and a portion of the first surface (S1) to protect the light-emitting device from environmental damages, such as moisture or mechanical harms. In some embodiments, the insulation layer 80 is made of a non-conductive material, an inorganic oxide material or a nitride material, or silicon dioxide, silicon nitride, titanium oxide, tantalum oxide, niobium oxide, barium titanate, magnesium fluoride, aluminum oxide, or combinations thereof. In some optional embodiments, during manufacturing of the light emitting device, a portion of the epitaxial structure 10 is etched to expose the current spreading layer 41 so as to form a mesa surface (MS). The insulation layer 80 extends from the sidewall of the epitaxial structure 10 to the mesa surface (MS) and covers the mesa surface (MS).

Referring to FIG. 2, in some embodiments, when the first surface (S1) is a light-emitting surface, the first surface (S1) of the epitaxial structure 10 is designed to be a roughened surface, which may increase light extraction efficiency. The roughened surface may be designed to have random patterns or regular patterns.

The light-emitting device, as shown in FIGS. 1 and 2, may further include a reflection layer 43, a substrate 60, and a second metal electrode 70.

The reflection layer 43 is disposed on the current transmission blocks 30 and the current blocking layer 42 away from the epitaxial structure 10. In some embodiments, the reflection layer 43 is a distributed Bragg reflector (DBR) and includes first layers and second layers that are alternately stacked, and a refractive index of each of the first layers is different from that of each of the second layers. The first layers and the second layers may be independently made of a dielectric oxide material including TiOₓ, SiOₓ, or AlOₓ. The reflection layer 43 may also be an Omni-directional reflector (ODR), which includes metal materials such as Al, Ag, Au, etc., and may be bonded with the DBR to form a total reflector. The current spreading layer 41 and a transparent conductive layer (not shown) may also be disposed on the reflection layer 43 to increase efficiency of the light-emitting device. In addition, the reflection layer 43 and the current blocking layer 42 together form a total internal reflection (TIR), which reflects light from the epitaxial structure 10 toward the substrate 60 back to the epitaxial structure 10, and then enables the light to exit from the first surface (S1), thereby improving light exiting efficiency.

The substrate 60 is disposed on the reflection layer 43 away from the epitaxial structure 10. The substrate 60 may be a conductive substrate and made of an opaque material. In some embodiments, the substrate 60 may be a conductive silicon substrate, a conductive metal substrate, or other conductive substrates.

Moreover, a bonding layer 50 may be disposed between the substrate 60 and the reflection layer 43. The bonding layer 50 may be made of a metal material which contains In, Sn, Au, Ti, Ni, Pt, W, or alloys thereof.

The second metal electrode 70 is disposed on the substrate 60 away from the epitaxial structure 10 for conducting current with the first metal electrode 20. In this embodiment, the second metal electrode 70 covers the substrate 60 entirely. The second metal electrode 70 may be made of a material which includes a metal material or a metal alloy material, specifically containing Au, Pt, GeAlNi, Ti, BeAu, GeAu, Al, ZnAu, etc.

In addition to the aforesaid structural features, other structural features may be added to the light-emitting device of the aforesaid embodiments to achieve corresponding purposes.

The present embodiment further provides a light-emitting apparatus including the light-emitting device of any one of the above embodiments and/or combinations thereof, and using a red light or an infrared light provided by the light-emitting device to display, illuminate, or provide use for other optical equipment.

In summary, compared to the conventional current transmission blocks, the current transmission blocks 30 of the light-emitting device provided by the present disclosure are improved so the current may be transmitted in a parallel manner spatially. In addition, by increasing the areas of the current transmission blocks 30 for current transmission, the current transmitted per unit of time may effectively be increased and faster transmission of the current and heat may be ensured to avoid current accumulation, thereby resolving high forward voltage, low hot-cold factor, and poor thermal saturation.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
an epitaxial structure that has a first surface and a second surface opposite to said first surface;
a first metal electrode that is disposed on said first surface of said epitaxial structure, said first metal electrode including a main electrode and a plurality of extending electrodes that extend in an extending direction;
a plurality of current transmission blocks that are disposed on said second surface of said epitaxial structure and that are disposed between two adjacent ones of said extending electrodes, wherein for each of said two adjacent ones of said extending electrodes, each of those of said current transmission blocks that are adjacent to one side of said extending electrode has an electrode-facing sidewall that faces said one side of said extending electrode, and that is non-curved and parallel to an imaginary perpendicular surface which passes through said extending electrode and extends in the extending direction, and a non-electrode-facing sidewall that is distal to said one side of said extending electrode, said imaginary perpendicular surface being a normal surface that is perpendicular to said first surface; and
a current blocking layer that is disposed in spaces among said current transmission blocks.

2. The light-emitting device as claimed in claim 1, wherein a projection of each of said current transmission blocks on said first surface of said epitaxial structure falls outside a projection of each of said extending electrodes on said first surface of said epitaxial structure.

3. The light-emitting device as claimed in claim 1, wherein said electrode-facing sidewall of each of said current transmission blocks are axisymmetric.

4. The light-emitting device as claimed in claim 3, wherein said current transmission blocks are prisms.

5. The light-emitting device as claimed in claim 4, wherein said current transmission blocks are hexagonal prisms, pentagonal prisms, and quadrangular prisms or combinations thereof.

6. The light-emitting device as claimed in claim 1, wherein for two adjacent ones of said extending electrodes, those of said current transmission blocks that are between said two adjacent ones of said extending electrodes are disposed in a symmetrical and uniform manner.

7. The light-emitting device as claimed in claim 1, wherein for each of said two adjacent ones of said extending electrodes, a projection, on said imaginary perpendicular surface, of said electrode-facing sidewall of each of said those of said current transmission blocks that faces said one side of said extending electrode has a length in the extending direction, and a ratio of a sum of the lengths of said projections of said electrode-facing sidewalls of said those of said current transmission blocks to a length of said extending electrode in the extending direction is no greater than 0.9.

8. The light-emitting device as claimed in claim 7, wherein the ratio ranges from 0.3 to 0.8.

9. The light-emitting device as claimed in claim 1, wherein said current blocking layer contains an oxide material, a nitride material, a fluoride material, or combinations thereof.

10. The light-emitting device as claimed in claim 1, further comprising a current spreading layer that is disposed between said epitaxial structure and said current blocking layer.

11. The light-emitting device as claimed in claim 1, further comprising an insulation layer that covers a sidewall of said epitaxial structure and a portion of said first surface.

12. The light-emitting device as claimed in claim 11, wherein said epitaxial structure includes a first semiconductor layer, an active layer, and a second semiconductor layer sequentially disposed in such order in a laminating direction from said first surface to said second surface.

13. The light-emitting device as claimed in claim 1, wherein said first surface of said epitaxial structure is a roughened surface.

14. The light-emitting device as claimed in claim 1, further comprising
a reflection layer that is disposed on said current blocking layer and said current transmission blocks away from said epitaxial structure,
a substrate that is disposed on said reflection layer away from said epitaxial structure, and
a second metal electrode that is disposed on said substrate away from said epitaxial structure.

15. The light-emitting device as claimed in claim 14, further comprising a bonding layer that is disposed between said substrate and said reflection layer.

16. A light-emitting apparatus comprising the light-emitting device as claimed in claim 1.
